(19) United States
(12) Patent Application Publication
(10) Pub. No.: US 2026/0287397 A1
(43) Pub. Date: Sep. 24, 2026

(54) SYSTEMS AND METHODS FOR UTILIZING TWO-DIMENSIONAL DISPLACEMENT FOR INDUCTIVE SENSING

(71) Applicant: Cirrus Logic International Semiconductor Ltd., Edinburgh (GB)

(72) Inventor: Caleb PETRIE, Austin, TX (US)

(73) Assignee: Cirrus Logic International Semiconductor Ltd., Edinburgh (GB)

(21) Appl. No.: 19/455,057

(22) Filed: Jan. 21, 2026

Related U.S. Application Data
(60) Provisional application No. 63/774,930, filed on Mar. 20, 2025.

(51) Int. Cl. G01D 5/20; G01R 27/26

(52) U.S. Cl. CPC G01D 5/202; G01R 27/2611

(57) ABSTRACT

An inductive sensing system may include an inductive coil, a conductive target having a conductive region with a spatially varying effective area positioned at a fixed separation distance from the inductive coil and magnetically coupled to the inductive coil such that a width of the conductive region in proximity to the inductive coil varies along a sensing path, and an inductance detector coupled to the inductive coil and configured to measure a parameter indicative of inductance of the inductive coil that varies with an overlap between the conductive region and the inductive coil such that the parameter varies with a position of the conductive target along the sensing path based on the parameter.

### CROSS-REFERENCES AND RELATED APPLICATION

The present disclosure claims priority to U.S. Provisional Patent Application No. 63/774,930, filed Mar. 20, 2025, which is incorporated by reference herein in its entirety.

### FIELD OF DISCLOSURE

The present disclosure relates in general to methods, apparatuses, or implementations for inductive sensing. Embodiments set forth herein may disclose utilization of two-dimensional displacement to perform inductive sensing.

### BACKGROUND

Position sensing technologies can be employed across a wide range of applications to determine the location, orientation, or movement of objects in two or three dimensions. Potential uses include industrial automation and robotics for tool positioning, part alignment, and closed-loop motion control; automotive systems for steering, throttle, gear-selection, occupant monitoring, and advanced driver-assistance functions; medical and surgical devices for instrument tracking, prosthetic control, imaging alignment, and patient positioning; consumer electronics and wearables for gesture recognition, user input, augmented/virtual reality tracking, and device docking; logistics and manufacturing for conveyor tracking, pick-and-place operations, and inventory localization; aerospace and drones for control-surface feedback, gimbal stabilization, and navigation; and security and smart infrastructure for access control, intrusion detection, and occupancy sensing. Such sensors may be configured to operate with conductive, magnetic, optical, or capacitive targets, and can be adapted for harsh, sterile, indoor, or outdoor environments, enabling contact or non-contact measurement suitable for linear, rotational, and multi-axis tracking in static or dynamic contexts.

In small or integrated circuit level electronics, such methods and solutions are dominated by potentiometers and Hall effect sensors which translate a change in position into a measurable parameter. These traditional approaches to measuring the position of an object tend to either be prone to physical wear and tear because of implementation of a low-cost solution (such as use of potentiometers) or may involve a high-cost solution (such as use of Hall effect sensors).

Potentiometers generally operate by whipping an output node across a resistive element (usually a graphite plane) resulting in a change in resistance across the range of movement of the device that can be detected by the host controller. Because of this physical whipping of the output node, the resistive element may break down over time to the point where some portions make little to no electrical contact or flakes of the resistive element may be displaced and end up where they should not be. Such breakdown may result in the resistance being inconsistent or jittery across the range of movement.

Hall effect sensors may utilize a Wheatstone bridge circuit, as is known in the art. In such a Wheatstone bridge circuit, one of four resistors of the circuit may be affected by a change in magnetic field, either increasing or decreasing the resistance proportional to the field. When used to measure translational or rotational movement, a magnet may be moved over the top of the sensor so that the movement results in a proportional change in resistance in the sensor. The use of a magnet in this approach may result in a highly reliable and accurate implementation, though greatly increasing the cost of the overall implementation.

### SUMMARY

In accordance with the teachings of the present disclosure, the disadvantages and problems associated with existing approaches for sensing displacement of an object may be reduced or eliminated.

In accordance with embodiments of the present disclosure, an inductive sensing system may include an inductive coil, a conductive target having a conductive region with a spatially varying effective area positioned at a fixed separation distance from the inductive coil and magnetically coupled to the inductive coil such that a width of the conductive region in proximity to the inductive coil varies along a sensing path, and an inductance detector coupled to the inductive coil and configured to measure a parameter indicative of inductance of the inductive coil that varies with an overlap between the conductive region and the inductive coil such that the parameter varies with a position of the conductive target along the sensing path based on the parameter.

In accordance with these and other embodiments of the present disclosure, a method of inductive sensing may include positioning a conductive target having a conductive region with a spatially varying effective area at a fixed separation distance from an inductive coil such that the conductive target is magnetically coupled to the inductive coil and a width of the conductive region in proximity to the inductive coil varies along a sensing path, translating the conductive target along the sensing path to vary an overlap between the conductive region and the inductive coil, measuring, with an inductance detector coupled to the inductive coil, a parameter indicative of an inductance of the inductive coil that varies with the overlap between the conductive region and the inductive coil, and determining a position of the conductive target along the sensing path based on the parameter.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1A illustrates a block diagram of a side elevation view of selected components of a linear inductive sensor, in accordance with embodiments of the present disclosure;

FIG. 1B illustrates a block diagram of a top-down plan view of selected components of the linear inductive sensor shown in FIG. 1A in a first position, in accordance with embodiments of the present disclosure;

FIG. 1C illustrates a block diagram of a top-down plan view of selected components of the linear inductive sensor shown in FIG. 1A in a second position, in accordance with embodiments of the present disclosure;

FIG. 1D illustrates a block diagram of a top-down plan view of selected components of the linear inductive sensor shown in FIG. 1A in a third position, in accordance with embodiments of the present disclosure;

FIG. 2A illustrates a block diagram of a side elevation view of selected components of a circular inductive sensor in a first position, in accordance with embodiments of the present disclosure;

FIG. 2B illustrates a block diagram of a side elevation view of selected components of the circular inductive sensor of FIG. 2A in a second position, in accordance with embodiments of the present disclosure;

FIG. 2C illustrates a block diagram of an isometric perspective view of selected components of the circular inductive sensor of FIGS. 2A and 2B in the first position, in accordance with embodiments of the present disclosure;

FIG. 2D illustrates a block diagram of an isometric perspective view of selected components of the circular inductive sensor of FIGS. 2A and 2B in the second position, in accordance with embodiments of the present disclosure; and

FIG. 3 illustrates a block/circuit diagram of an example circuit for detecting position-dependent inductance of a two-dimensional inductive sensor, in accordance with embodiments of the present disclosure.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiment discussed below, and all such equivalents should be deemed as being encompassed by the present disclosure.

In accordance with embodiments of the present disclosure, inductive sense solutions may utilize a fixed capacitor and an inductive coil to create an inductive-capacitive (LC) tank at a given resonance frequency. Traditionally, by moving a magnetically coupled piece of metal, usually copper, closer or further away from the coil, the resulting inductance of the coil is altered due to eddy currents in the magnetically coupled piece of metal. This altered inductance changes the resonant frequency of the LC tank which is measured by an inductive sensing device or integrated circuit (IC) as a phase shift from the original resonant frequency.

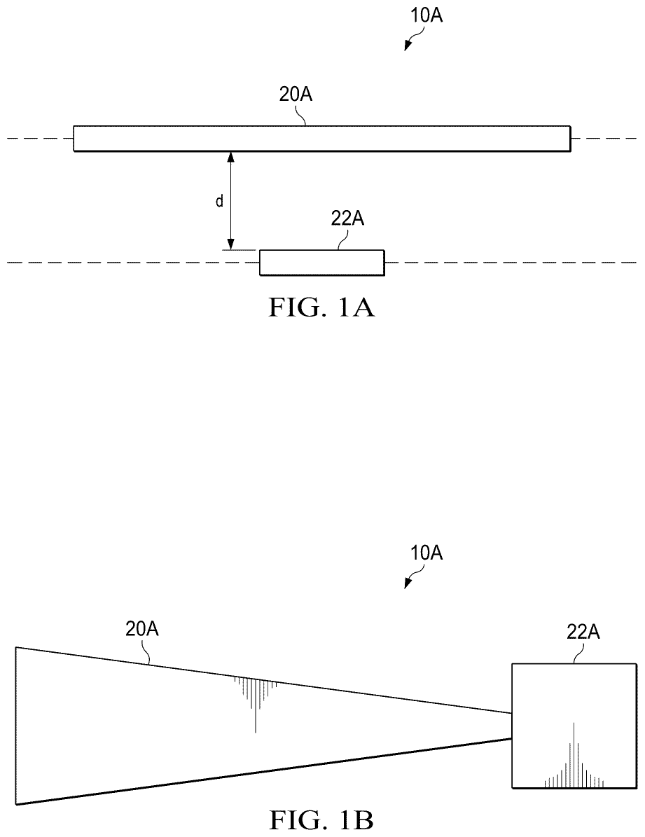

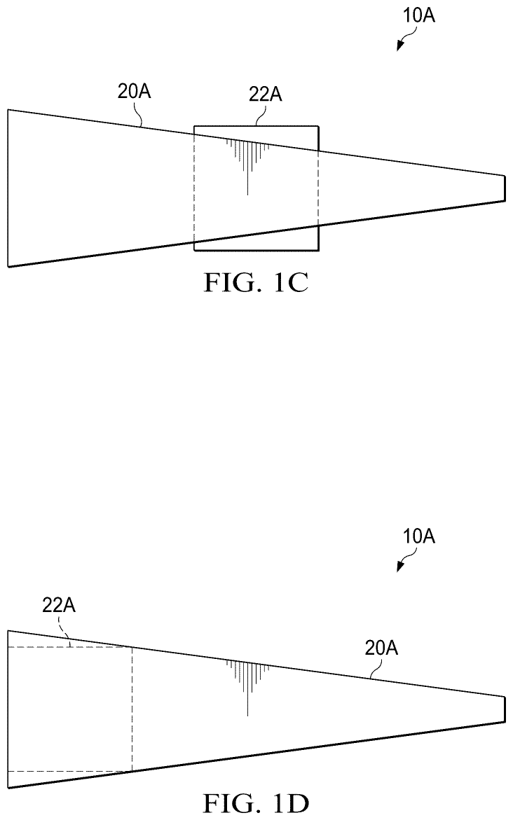

FIG. 1A illustrates a block diagram of a side elevation view of selected components of a linear inductive sensor 10A, in accordance with embodiments of the present disclosure. As shown in FIG. 1A, a metal target 20A (e.g., a substantially planar metal sheet) may be placed in parallel with and at a fixed distance d from an inductive coil 22A and may be magnetically coupled to inductive coil 22A.

FIG. 1B illustrates a block diagram of a top-down plan view of selected components of linear inductive sensor 10A in a first position, in accordance with embodiments of the present disclosure. FIG. 1C illustrates a block diagram of a top-down plan view of selected components of linear inductive sensor 10A in a second position, in accordance with embodiments of the present disclosure. FIG. 1D illustrates a block diagram of a top-down plan view of selected components of linear inductive sensor 10A in a third position, in accordance with embodiments of the present disclosure. In some embodiments, the tapered shaped of metal target 20A may be designed such that one end fully covers inductive coil 22A and linearly tapers down to a minimal width at the opposite end. For example, the first position may represent 0 percent of the available sensing range of linear inductive sensor 10A, the second position may represent 50 percent of the available sensing range of linear inductive sensor 10A, and the third position may represent 100 percent of the available sensing range of linear inductive sensor 10A.

As shown in FIGS. 1B-1D, metal target 20A may have a triangular or trapezoidal shape such that a width of metal target 20A tapers continuously and linearly across a desired range of motion of metal target 20A relative to inductive coil 22A, with any remaining width outside of the desired range of motion being either fixed or nonexistent (with the width outside of the desired range of motion being nonexistent in examples represented by FIGS. 1B-1D).

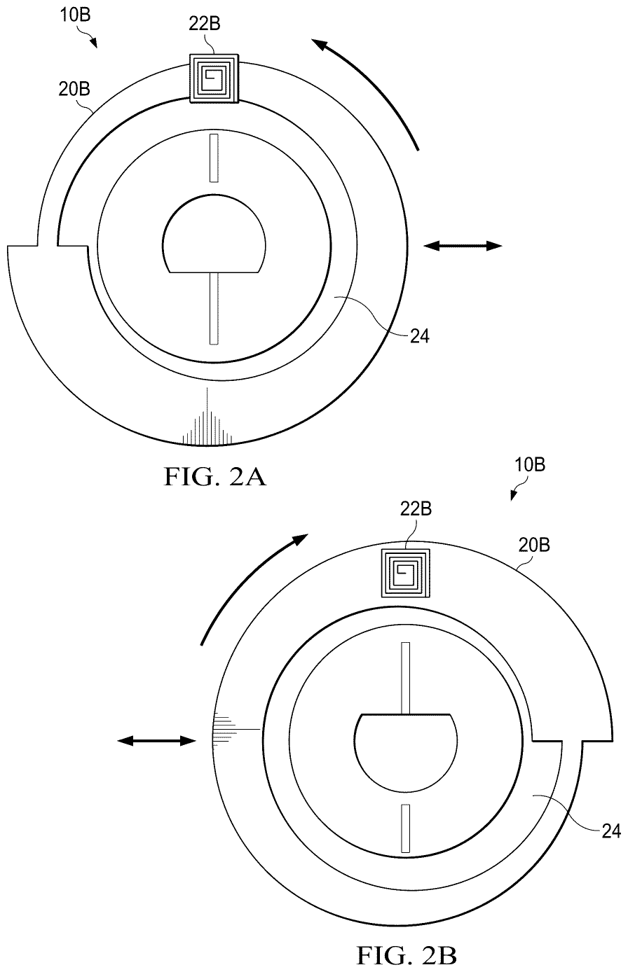

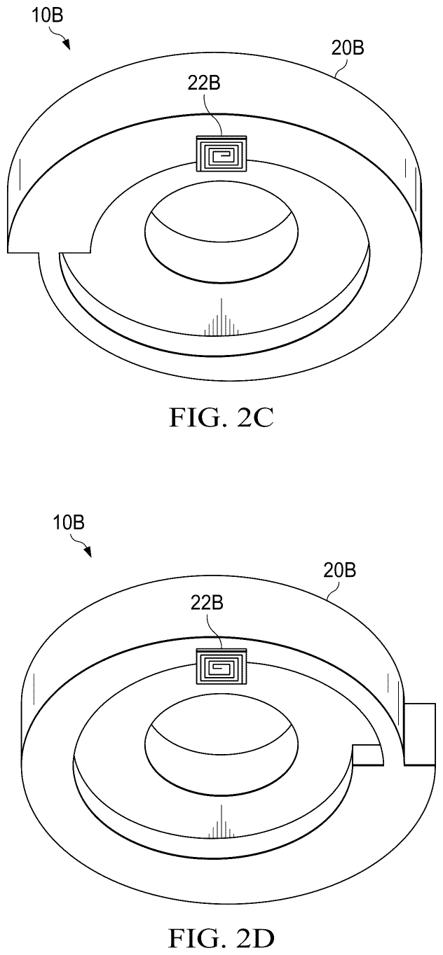

FIG. 2A illustrates a block diagram of a side elevation view of selected components of a circular inductive sensor 10B in a first position, in accordance with embodiments of the present disclosure. FIG. 2B illustrates a block diagram of a side elevation view of selected components of circular inductive sensor 10B in a second position, in accordance with embodiments of the present disclosure. FIG. 2C illustrates a block diagram of an isometric perspective view of selected components of circular inductive sensor 10B in the first position, in accordance with embodiments of the present disclosure. FIG. 2D illustrates a block diagram of an isometric perspective view of selected components of circular inductive sensor 10B in the second position, in accordance with embodiments of the present disclosure. As shown in FIGS. 2A-2D, metal target 20B may have a crescent shape and may be placed a fixed distance from inductive coil 22B such that metal target 20B is magnetically coupled to inductive coil 22B. As shown in FIGS. 2A-2D, circular inductive sensor 10B may further include a spacer 24 around which metal target 20B may surround. As further shown in FIGS. 2A-2D, a shape of metal target 20B may taper linearly for a least a portion of a circumference of a circle for a desired range of motion (e.g., a desired range of angles) of metal target 20B relative to inductive coil 22B, with any remaining width outside of the desired range of motion being either fixed or nonexistent (with the width outside of the desired range of motion being nonexistent in examples represented by FIGS. 2A-2D). In some embodiments, the first position and the second position may be approximately 180 degrees from each other.

In operation, instead of moving a metal target closer to or further from an inductive coil, as is typically done in traditional approaches to inductive-based sensing, the systems and methods herein may use a taper-shaped metal target 20 (e.g., metal target 20A or metal target 20B) placed at an optimal fixed distance from an inductive coil 22 (e.g., inductive coil 22A or inductive coil 22B), and may be translated relative to the inductive coil 22 (e.g., at the fixed distance) to vary an overlap between the metal target 20 and the inductive coil 22. As the taper-shaped feature of the metal target 20 translates relative to the inductive coil 22 (e.g., proximate to the center of the inductive coil 22), the inductance of the inductive coil 22 may change and may be measured to determine the position of the metal target 20 relative to the inductive coil 22.

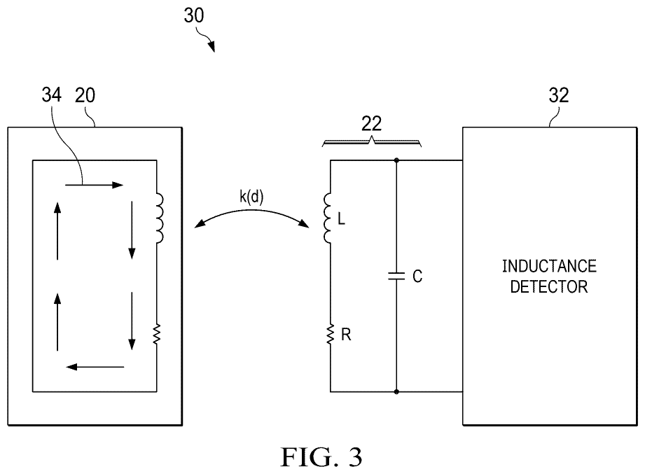

FIG. 3 illustrates a block/circuit diagram of an example circuit 30 for detecting position-dependent inductance of a two-dimensional inductive sensor (e.g., linear inductive sensor 10A or circular inductive sensor 10B), in accordance with embodiments of the present disclosure. FIG. 3 illustrates interactions and relationships among a metal target 20 (e.g., metal target 20A or metal target 20B), an inductive coil 22 (e.g., inductive coil 22A or inductive coil 22B) and an inductance detector 32. As shown in FIG. 3, inductive coil 22 may be modeled with an inductance L, a resistance R in series with inductance L, and a capacitance in parallel with the series combination of inductance L and resistance R. As further shown, a distance-dependent mutual inductance k(d) may exist between metal target 20 and inductance L.

When more conductive surface of metal coil 20 is present in proximity to inductive coil 22, a higher amount of Eddy currents 34 may be induced into an alternating current magnetic field of inductive sensor 10, resulting in a change in phase or a change in resonant frequency of the resonant tank formed by inductance L and capacitance C. Further, when less conductive surface of metal coil 20 is present in proximity to inductive coil 22, a lower amount of Eddy currents 34 may be induced into an alternating current magnetic field of inductive sensor 10, resulting in a change in an opposite phase or an opposite change in resonant frequency of the resonant tank formed by inductance L and capacitance C.

Although the description above contemplates a conductive target with a taper- or crescent-shaped conductive region, the systems and methods herein may be applied to any suitable conductive target with a spatially varying effective area such that a width of the conductive region in proximity to an inductive coil varies along a sensing path.

Accordingly, systems and methods are provided in which an inductive sensing device comprises an inductive coil magnetically coupled to a taper-shaped metal target. An amount of inductance that is sensed by the inductive sensing device depends on an amount of width of the taper-shaped metal target being in proximity to the inductive coil. For example, an inductance sensed by an inductance detector coupled to the inductive sensing device may be larger when a larger amount of width of the taper-shaped metal target is in proximity to the inductive coil. As a further example, an inductance sensed by an inductance detector coupled to the inductive sensing device may be smaller when a smaller amount of width of the taper-shaped metal target is in proximity to the inductive coil.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

Further, reciting in the appended claims that a structure is “configured to” or “operable to” perform one or more tasks is expressly intended not to invoke 35 U.S.C. §112(f) for that claim element. Accordingly, none of the claims in this application as filed are intended to be interpreted as having means-plus-function elements. Should Applicant wish to invoke §112(f) during prosecution, Applicant will recite claim elements using the “means for [performing a function]” construct.

What is claimed is:

1. An inductive sensing system, comprising:
an inductive coil;
a conductive target having a conductive region with a spatially varying effective area positioned at a fixed separation distance from the inductive coil and magnetically coupled to the inductive coil such that a width of the conductive region in proximity to the inductive coil varies along a sensing path; and
an inductance detector coupled to the inductive coil and configured to measure a parameter indicative of inductance of the inductive coil that varies with an overlap between the conductive region and the inductive coil such that the parameter varies with a position of the conductive target along the sensing path based on the parameter.

2. The system of claim 1, wherein the conductive region is a taper-shaped region.

3. The system of claim 1, wherein the conductive region comprises a linear taper in width such that the width varies substantially linearly with the position of the conductive target along the sensing path.

4. The system of claim 1, wherein the conductive target comprises a substantially planar metallic sheet having a triangular or trapezoidal form that provides the conductive region across a range of linear motion.

5. The system of claim 1, wherein the conductive target comprises a crescent-shaped metallic sheet having the conductive region across a range of angular motion about an axis substantially normal to a plane of the inductive coil.

6. The system of claim 1, wherein an inductance of the inductive coil forms at least a portion of a resonant circuit, and wherein the parameter comprises a resonant frequency or a phase of the resonant circuit.

7. The system of claim 1, wherein the system is configured to establish endpoints of a measurement range by positioning the conductive region so that, at a first endpoint, the conductive target substantially covers the inductive coil and, at a second endpoint, the conductive target minimally overlaps the inductive coil.

8. The system of claim 1, wherein the conductive region is arranged to pass proximate to a central portion of the inductive coil throughout the sensing path.

9. The system of claim 1, wherein the inductive coil has a circular form and the sensing path is rotational about an axis, the conductive region varying in width along at least a portion of a circumference of the circular form.

10. A method of inductive sensing, the method comprising:
positioning a conductive target having a conductive region with a spatially varying effective area at a fixed separation distance from an inductive coil such that the conductive target is magnetically coupled to the inductive coil and a width of the conductive region in proximity to the inductive coil varies along a sensing path;
translating the conductive target along the sensing path to vary an overlap between the conductive region and the inductive coil;
measuring, with an inductance detector coupled to the inductive coil, a parameter indicative of an inductance of the inductive coil that varies with the overlap between the conductive region and the inductive coil; and
determining a position of the conductive target along the sensing path based on the parameter.

11. The method of claim 10, wherein the conductive region is a taper-shaped region.

12. The method of claim 10, wherein the conductive region comprises a linear taper in width such that the width varies substantially linearly with the position of the conductive target along the sensing path.

13. The method of claim 10, wherein the conductive target comprises a substantially planar metallic sheet having a triangular or trapezoidal form that provides the conductive region across a range of linear motion.

14. The method of claim 10, wherein the conductive target comprises a crescent-shaped metallic sheet having the conductive region across a range of angular motion about an axis substantially normal to a plane of the inductive coil.

15. The method of claim 10, wherein an inductance of the inductive coil forms at least a portion of a resonant circuit, and wherein the parameter comprises a resonant frequency or a phase of the resonant circuit.

16. The method of claim 10, further comprising establishing endpoints of a measurement range by positioning the conductive region so that, at a first endpoint, the conductive target substantially covers the inductive coil and, at a second endpoint, the conductive target minimally overlaps the inductive coil.

17. The method of claim 10, wherein translating the conductive target along the sensing path comprises arranging the conductive region to pass proximate to a central portion of the inductive coil throughout the sensing path.

18. The method of claim 10, wherein the inductive coil has a circular form and the sensing path is rotational about an axis, and wherein the conductive region varies in width along at least a portion of a circumference of the circular form.
